(19) United States
(12) Patent Application Publication
(10) Pub. No.: US 2005/0179024 A1
(43) Pub. Date: Aug. 18, 2005

(54) Electron emission material and electron emission element using the same

(75) Inventors: Motoshi Shibata, Nara (JP); Masahiro Deguchi, Osaka (JP); Akira Taomoto, Kyoto (JP); Toyokazu Ozaki, Nara (JP)

Correspondence Address: McDERMOTT WILL & EMERY LLP, 600 13th Street, N.W., Washington, DC, 20005-3096, US

(73) Assignee: MATSUSHITA ELECTRIC INDUSTRIAL CO., LTD., Osaka (JP)

(21) Appl. No.: 11/102,628

(22) Filed: Apr. 11, 2005

Related U.S. Application Data
(63) Continuation-in-part of application No. PCT/JP04/18937, filed on Dec. 17, 2004.

(30) Foreign Application Priority Data
Dec. 25, 2003 (JP) 2003-429437
Feb. 4, 2004 (JP) 2004-027633

(51) Int. Cl. H01L 29/06

(52) U.S. Cl. 257/10

(57) ABSTRACT

Provided are an electron emission material having a reduced work function, and an electron emission element that has lower power consumption and/or high current density and exhibits excellent electron emission performance. An electron emission material includes a semiconductor substrate having atomic steps on a surface thereof and a flat region between two of the atomic steps adjacent to each other, and an adsorbed layer arranged in the flat region. The adsorbed layer contains at least one element selected from an alkali metal element, an alkaline-earth metal element, and Sc.

### BACKGROUND OF THE INVENTION

1. Field of the Invention

The present invention relates to an electron emission material including a semiconductor, and an electron emission element using the material.

2. Description of Related Art

Conventionally, electron emission materials made of metal oxide have been widely used for electron sources of various devices such as cathode-ray tubes. The electron emission materials require high temperatures to emit electrons. For example, an electron emission material made of a mixture of barium oxide, strontium oxide, and calcium oxide requires a temperature of about 660° C. to 670° C. to attain a current density of 1 A/cm².

In recent years, electron emission materials with a reduced work function have been demanded to improve the performance (specifically, to increase the current density or reduce the power consumption) of the electron sources. A reduced work function makes it possible to attain a larger current density at a lower temperature, as seen from the Richardson-Dushmann equation (Equation (1) below). However, among the electron emission materials made of metal oxide, no material has been found to be superior to the foregoing mixture (work function: about 1.5 eV).
J=AT²·exp(−qφ/kBT) (1)

(In the equation, J is work volume (J), which reflects an obtained current density in cases of electron emission materials. A and q are constants, T is absolute temperature (K), φ is work function (J), and kB is Boltzmann constant.)

Meanwhile, electron emission materials containing a semiconductor have been known, in addition to the electron emission materials made of metal oxide. The electron emission materials containing a semiconductor is capable of reducing the work function by depositing an element that is different from the element(s) that constitute/constitutes the semiconductor on its surface. For example, J. Vac. Sci. Technol. B, vol. 16, 2224 (1998) reports the relationship between the work function and the amount of Cs deposited on the GaN (0001) surface. According to the report, as the amount of Cs deposited increases, the work function rapidly decreases from the value on a clean GaN surface, reaches the minimum value, and then gradually approximates to the value of Cs itself. Specifically, the deposition of Cs enables the electron emission material to have a work function less than those of the substrate (GaN) and the deposited substance (Cs) itself.

Although the reason why the work function can be reduced has not been clearly understood, the following model has been proposed: since the element constituting the semiconductor and the element deposited on the surface thereof have different electronegativity values, an electric dipole is formed in the deposited region on the semiconductor surface. The electric field induced by the electric dipole changes the state of electrons in the semiconductor surface, reducing the work function. This model can explain the phenomenon qualitatively and is therefore widely used.

JP H09(1997)-223455A discloses a material in which atoms 103 of an alkali metal, an alkaline-earth metal, or an oxide thereof are adsorbed onto step sites 104 on a metal substrate 101 composed of tungsten and having periodic atomic steps on a surface thereof, whereby the work function is reduced (FIG. 16). Example 1 of JP H09(1997)-223455A shows that the work function can be further reduced when the (110) surface of the tungsten substrate has an inclination angle of 6° or greater (in other words, when the step interval 102 shown in FIG. 16 is 2.5 nm or less) (FIG. 17). In FIG. 17, the vertical axis represents the profile of work function (eV) and the horizontal axis represents inclination angle (°) of the substrate.

Thus, it has been expected to develop of a method for reducing the work function in an electron emission material containing a semiconductor by arranging, on a surface thereof, an element that is different from the element constituting the semiconductor. However, since the surface structure of semiconductor is susceptible to heat, the electron emission material containing a semiconductor requires a greater degree of reduction in the work function than is necessary for the electron emission material composed of a metal oxide, in order to produce a viable electron emission material. Such an electron emission material has not yet been developed.

### BRIEF SUMMARY OF THE INVENTION

In accordance with the present invention, an electron emission material includes: a semiconductor substrate having a plurality of atomic steps on a surface thereof and a flat region between two of the atomic steps adjacent to each other; and an adsorbed layer arranged in the flat region; wherein the adsorbed layer contains at least one element selected from an alkali metal element, an alkaline-earth metal element, and Sc.

Such an electron emission material can be fabricated through a deposition step of depositing at least one element selected from an alkali metal element, an alkaline-earth metal element, and Sc, on a semiconductor substrate a surface of which has a plurality of atomic steps and a flat region between two of the atomic steps adjacent to each other. By such a deposition step, at least one element selected from an alkali metal element, an alkaline-earth metal element, and Sc is arranged as an adsorbed layer in the flat region.

In accordance with the present invention, an electron emission element includes: an electron emission layer including an electron emission material; and an electrode arranged so as to oppose the electron emission layer and adapted to generate a potential difference between the electrode and the electron emission layer; wherein the electron emission material includes a semiconductor substrate having a plurality of atomic steps on a surface thereof, and a flat region between two of the atomic steps adjacent to each other; and an adsorbed layer arranged in the flat region; and the adsorbed layer contains at least one element selected from an alkali metal element, an alkaline-earth metal element, and Sc.

### BRIEF DESCRIPTION OF THE DRAWINGS

FIG. 1 is a view schematically illustrating an example of the structure of an electron emission material according to the present invention;

FIG. 2 is a view schematically illustrating a region in the vicinity of the surface of the semiconductor substrate in the electron emission material shown in FIG. 1;

FIG. 3 is a view schematically illustrating another example of the structure of the electron emission material according to the present invention;

FIG. 4 is a schematic view for explaining an example of the structure of the surface in an electron emission material according to the present invention;

FIG. 5 is a view schematically illustrating yet another example of the structure of the electron emission material according to the present invention;

FIG. 6 is a view schematically illustrating a portion of the semiconductor substrate in the electron emission material shown in FIG. 5;

FIG. 7 is a view schematically illustrating further another example of the structure of the electron emission material according to the present invention;

FIG. 8 is a cross-sectional view schematically illustrating an example of an electron emission element according to the present invention;

FIG. 9 is a view schematically illustrating the surface condition of an electron emission material of the present invention, fabricated in an Example;

FIG. 10 is a view schematically illustrating the structure of the surface of a semiconductor substrate used in an Example;

FIG. 11 is a view schematically illustrating the structure of the surface of a semiconductor substrate used in an Example;

FIGS. 12A and 12B are views schematically illustrating process steps in an example of a method of manufacturing an electron emission element according to the present invention;

FIGS. 13A and 13B are views schematically illustrating process steps in another example of a method of manufacturing an electron emission element according to the present invention;

FIG. 14 is a view schematically illustrating an example of a change in the surface structure in the semiconductor substrate shown in FIG. 13A;

FIGS. 15A to 15C are views schematically illustrating process steps in yet another example of a method of manufacturing an electron emission element according to the present invention;

FIG. 16 is a schematic view illustrating an example of the structure of the surface in a conventional electron emission material; and

FIG. 17 is a graph illustrating an example of measurement results of work function for the conventional electron emission material.

### DETAILED DESCRIPTION OF THE INVENTION

Hereinbelow, preferred embodiments of the present invention are described with reference to the drawings. In the following description, identical components are denoted by identical reference numerals, and the same description thereof may be omitted.

An electron emission material according to the present invention is discussed.

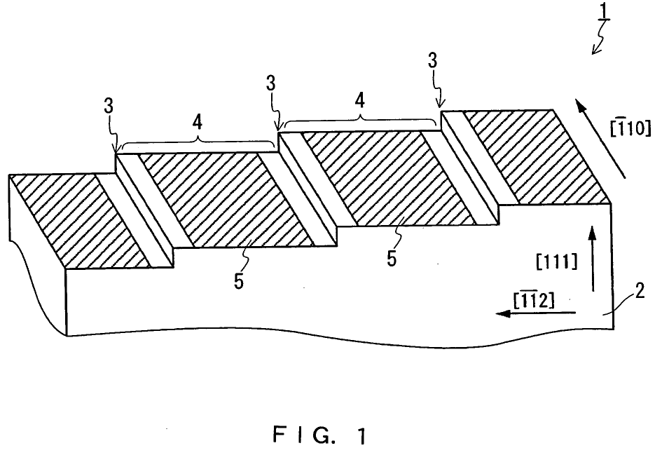

FIG. 1 shows an example of the electron emission material according to the present invention. An electron emission material 1 shown in FIG. 1 has a structure in which an adsorbed layer 5 is arranged on a flat region (terraced surface) 4 of a semiconductor substrate 2 (hereafter also referred to as “substrate 2”), a surface of which has a plurality of atomic steps 3. As shown in FIG. 1, the flat region 4 is positioned between the atomic steps 3 that are adjacent to each other.

The adsorbed layer 5 contains at least one element A selected from an alkali metal element, an alkaline-earth metal element, and Sc (scandium). This configuration enables the electron emission material 1 to have a reduced work function.

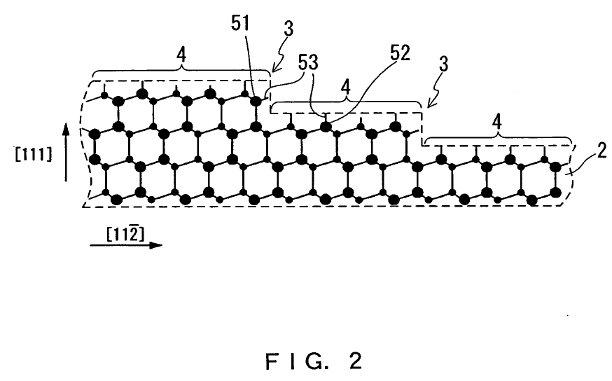

FIG. 2 shows a region in the vicinity of the surface of the substrate 2 in the electron emission material 1 shown in FIG. 1. As shown in FIG. 2, the directions and the numbers of unbonded sites (dangling bonds) 53 are different between atoms 51 located in the atomic steps 3 and atoms 52 located in the flat regions 4 because neighboring atoms have different arrangements between the atoms 51 and the atoms 52. For this reason, deviation in the distribution of charges in the surface of the substrate 2 occurs in the vicinity of the atomic step 3, and arrays of electric dipoles are formed in the direction along the atomic step 3 (the direction perpendicular to the plane of the drawing in FIG. 2). It is believed that the formation of electric dipoles changes the state of electrons in the surface of the substrate 2, thereby reducing the work function. That is, first, the electron emission material 1 achieves reduction in the work function by employing the substrate 2 in which the atomic steps 3 exists on the surface. It should be noted that in FIG. 2, the sizes of the black dots indicate positional relationships between the atoms (the atoms represented by large dots are positioned nearer), and the adsorbed layer 5 is not shown for clarity in illustration.

Second, in the electron emission material 1, the adsorbed layer 5 containing an element A is arranged in the flat region 4 of the substrate 2. By providing the adsorbed layer 5, an electric dipole is further formed between the atoms of the substrate that are in the flat region 4 and the element A that is adjacent thereto (i.e., the atoms of the element A adjacent thereto). Since the electric field shielding effect of carriers is relatively small in semiconductors, the effect of the electric field induced the electric dipole is believed to extend typically to the range of about several nanometers. Specifically, in the electron emission material of the present invention, the dipole moment induced by the atomic step and the dipole moment induced by the adsorbed layer provided in the flat region work synergistically, and thus the work function can be reduced further in comparison with an electron emission material including a substrate having the atomic steps only. This kind of structure can be formed by, for example, controlling the amount of the element A arranged (the amount of the element A deposited) and/or the temperature in arranging the element A in the flat regions 4.

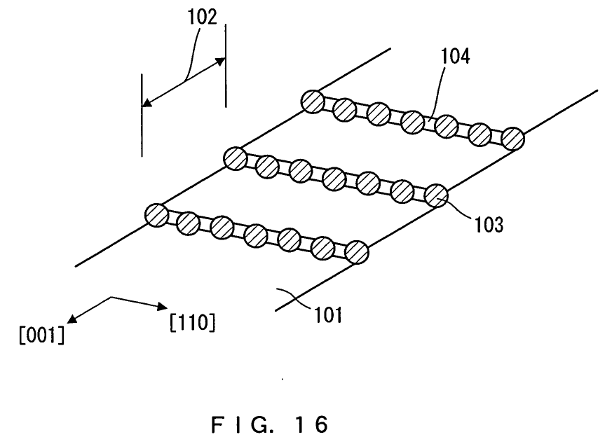

In the electron emission material disclosed in JP H09(1997)-223455A, an alkali metal element, an alkaline-earth metal element, or an oxide thereof is arranged on atomic steps (on step sites) (cf. FIG. 16), but no element is arranged on the flat regions. With such a configuration as well, a dipole moment is induced in the vicinity of the atomic step by the arranged element. Nevertheless, almost no dipole moment is induced in the flat regions, and the interaction between the dipole moment near the atomic step and the dipole moment in the flat region cannot be obtained. Therefore, with the electron emission material disclosed in JP H09(1997)-223455A, it is difficult to reduce the work function as is possible with the electron emission material of the present invention.

It is recommended that when there exist two or more flat regions 4, the adsorbed layer 5 be arranged on at least one of the flat regions 4. In each of the flat regions 4, the adsorbed layer 5 may be arranged in at least a portion of each of the flat regions 4. It is also possible that the element A may be arranged on a portion of the substrate 2 other than the flat region 4 (for example, on the atomic step (step site) 3).

It is preferable that the element A be at least one element selected from Li (lithium), Na (sodium), K (potassium), Rb (rubidium), Cs (cesium), Ca (calcium), Sr (strontium), Ba (barium), and Sc (scandium), and more preferably, one element selected from Cs, Ba, Ca, and Sc. These elements have greater effect to form electric dipoles and change the state of electrons in the surface of the substrate 2, and can reduce the work function further.

The adsorbed layer 5 may contain an element other than the element A, and may preferably further contain oxygen. In this case, the magnitude of the electric dipole formed can be increased, and the work function can be reduced further. The state of the oxygen in the adsorbed layer 5 is not particularly limited, but it is preferable that the oxygen be chemically bonded with the element A.

The material of the substrate 2 is not particularly limited, and, for example, either elemental semiconductors of Si etc., or compound semiconductors may be used. When using an elemental semiconductor, a crystalline Si semiconductor is preferable from the viewpoint of the easiness of fabricating atomic steps and the later-described crystal surface. The crystalline Si semiconductors include crystalline SiGe semiconductor, which contains Ge, crystalline SiC semiconductor, which contains C, and crystalline SiGeC semiconductor, which contains Ge and C. Strictly speaking, the crystalline Si semiconductor that does not contain Ge or C can be defined as “a semiconductor consisting only of crystalline Si.” When using a compound semiconductor, preferably used are a compound semiconductor that contains a Group IIIb element and a Group Vb element (such as GaAs, InGaAs, InP, GaN, and AlN), and a compound semiconductor that contains a Group IIb element and a Group VIb element (such as ZnSe, ZnTe, CdTe, and ZnO).

The flat region 4 is a region between atomic steps 3 in the surface of the substrate 2, which is also generally referred to as a terraced face (or simply as “terrace”).

It is preferable that the flat region 4 be a crystal surface represented by a plane index (hkl) (the flat region 4 shown in FIG. 1 is a crystal surface represented by a plane index (111)). In the plane index, h, k and l satisfy the expressions 0≦h≦3, 0<k≦3, and 0≦l<3, and at least two values selected from h, k and l are positive (two or more values selected from h, k and l cannot be 0 at once). In this case, the magnitude of the electric dipole formed between the flat region 4 and the adsorbed layer 5 can be increased. In addition, a greater electric dipole can be formed near the atomic step 3, and moreover, the shape of the atomic step can be made into substantially a straight line at an atomic level in its longitudinal direction. Therefore, it is possible to produce an electron emission material in which the work function can be reduced further. It should be noted that the foregoing preferable conditions cannot be applied when the substrate 2 has a hexagonal morphology (for example, when the material of the substrate 2 is ZnO, GaN, AlN, and the like) because the crystal surface of the flat region 4 cannot be represented by a plane index (hkl).

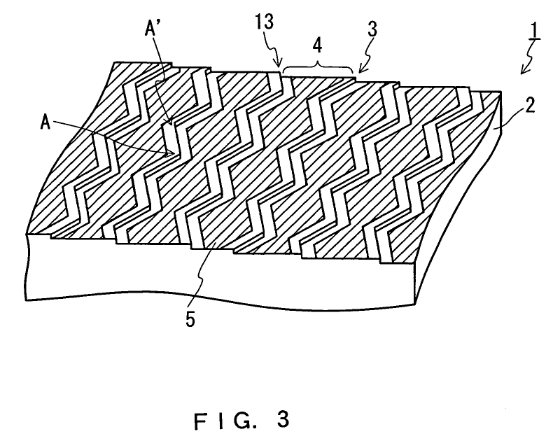

Although the shape of the flat region 4 is not particularly limited, it is preferable that the longitudinal directions of the atomic steps 3 adjacent to each other be substantially parallel to each other. The state of electrons in the surface of the substrate 2 can be changed to a state by which the work function can be further reduced. In this case, the length of the flat region 4 perpendicular to the longitudinal direction of the atomic step 3 (the width of the flat region 4) may be substantially constant, as illustrated in FIG. 1, or may vary periodically, as illustrated in FIG. 3. When the width of the flat region 4 varies periodically, the shape of the flat region 4 is not particularly limited and the flat region 4 may be formed by atomic steps 3 in a zigzag pattern, as illustrated in FIG. 3. In the electron emission material 1 shown in FIG. 3, the magnitude of the electric dipole can be increased at angular portions in the atomic step 3 (A and A′ in FIG. 3).

Although not particularly limited, the width of the flat region 4 may be, for example, 100 nm or less, and preferably, 10 nm or less. Although not particularly limited, the lower limit of the width of the flat region 4 may be, for example, 1 nm or greater, and it is preferable that the width of the flat region 4 be equal to or greater than the size of the unit cell formed by the element contained in the adsorbed layer 5. When the width of the flat region 4 is varied periodically, the minimum value thereof should be applied to the foregoing condition.

The structure of the adsorbed layer 5 is not particularly limited as long as it contains the element A; but it is preferable that the element A is arranged on a portion of the adsorption sites (for example, dangling bonds) existing in the surface of the flat region 4. This makes it possible to further optimize the state of the electric dipole formed between the adsorbed layer 5 and the flat region 4, in comparison with the case in which the element A is arranged onto all the adsorption sites. Such an adsorbed layer 5 can be formed by, for example, controlling the amount of the element A disposed (the amount of element A deposited) when arranging the element A on the flat region 4.

It is preferable that the adsorbed layer 5 have a structure in which the element A are aligned periodically. As has been described above, in the electron emission material 1 of the present invention, the adsorbed layer 5 is arranged in the flat region 4, and a low work function is achieved by the electric dipole formed between the adsorbed layer 5 and the flat region 4. Under this condition, due to the periodic alignment of the element A, a periodic alignment of dipole moments induced by the electric dipole is possible, making it possible to obtain a further greater dipole moment.

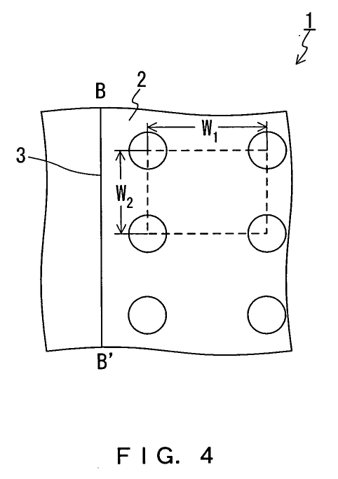

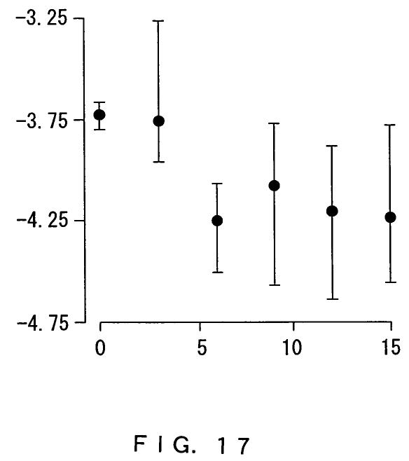

Although the alignment of the element A in the adsorbed layer 5 is not particularly limited, it is preferable that the interval between the element A be greater along the direction perpendicular to the longitudinal direction (B-B′) of the atomic step 3 (or along a direction different from the longitudinal direction) than that along the longitudinal direction (W₁>W₂), as illustrated in FIG. 4. It is believed that such a structure suppresses the occurrence of fluctuation (for example, meander-like shape) in the shape of the atomic step 3 at an atomic level, and suppresses fluctuation in the alignment of dipole moments induced along the atomic step 3. Thus, the electron emission material is enabled to have a further reduced work function. The measurement result for Example 1 of JP H09(1997)-223455A, illustrated in FIG. 17, shows that the work function obtained is unstable and the values exhibit a large error range, and it is believed that part of the cause of this error range is the above-mentioned fluctuation. The electron emission material 1 illustrated in FIG. 4 can reduce such a fluctuation in the work function, achieving a stable electron emission material. It should be noted that in FIG. 4, for clarity in illustration, the atomic step 3 is denoted by a straight line, and the atoms of the element A are schematically denoted by circles. Likewise, the unit of periodic alignment in the element A (unit cell) is denoted by dashed lines, and the arrangement of the element A with in the unit cell is not shown.

In addition, it is preferable that the alignment of the element A in the adsorbed layer 5 can be represented by a M×N structure (M and N are natural numbers satisfying the expression M>2N). Here, the M×N structure means a structure in which the size of the unit cell of the element A in the adsorbed layer 5 is M and N times of a primitive unit cell (1×1 structure) of the substrate 2 in the flat region 4 when viewed in plan from the direction perpendicular to the flat region 4. Such a structure can further suppress the occurrence of fluctuation in the shape of the atomic step 3 at an atomic level, and can further suppress fluctuation in the alignment of dipole moments induced along the atomic step 3. Thus, the electron emission material is enabled to have a further reduced work function and be stable.

When the alignment of the element A in the adsorbed layer 5 can be represented by an M×N structure, it is preferable that the unit cell of the element A be N times of the unit cell of the substrate 2, along the longitudinal direction of the atomic step 3. In other words, it is preferable that in the alignment of the atoms of the element A that can be represented by the M×N structure, the value corresponding to the alignment along the longitudinal direction of the atomic step 3 be N.

The M and N values can be controlled by, for example, selecting the types of the element contained in the substrate 2 and/or the element A, or controlling the amount of the element A disposed in the flat region 4 (the amount of the element A deposited).

The shape of the electron emission material 1 is not particularly limited and may be in a particle form or in a plate-like form (in other words, the shape of the substrate 2 is not limited and may be in a particle form or in a plate-like form). The electron emission material 1 in a plate-like form can be formed, for example, by using a semiconductor base plate having an atomic step 3 on its surface as the substrate 2 and arranging an adsorbed layer 5 in a flat region 4 thereof The electron emission material 1 in a particle form can be formed by, for example, pulverizing the above-mentioned electron emission material 1 in a plate-like form.

In forming the electron emission material 1, a base plate having a surface inclined in a predetermined direction and at a predetermined angle from the plane index of the flat region 4 may be used as a semiconductor base plate used for the substrate 2. By selecting the inclination direction and/or the inclination angle, the density and/or direction of the atomic step on the surface of the base plate can be controlled, making it easy to control the structure of the adsorbed layer 5.

In addition, a base plate in which an atomic step 3 is formed by a growth technique or etching may be used as a semiconductor base plate for the substrate 2. These methods can control the density and/or direction of the atomic step on the surface of the base plate, making it easy to control the structure of the adsorbed layer 5. Moreover, the atomic step may be formed at any position and at any density in the semiconductor base plate. With the growth technique or the etching, the growth or the etching may be stopped at the time when, for example, the atomic steps reaches a predetermined density.

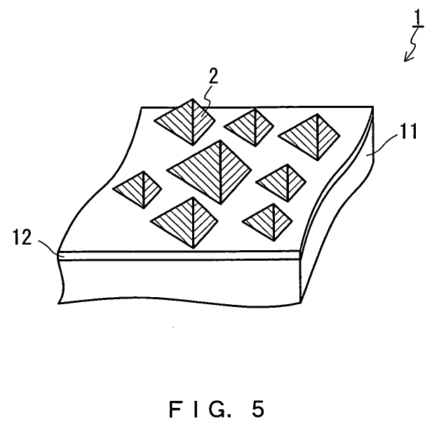

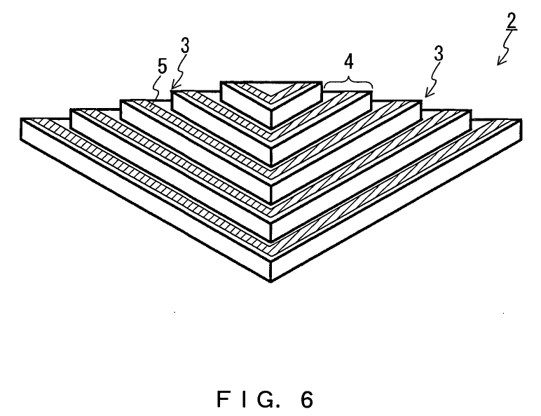

The substrate 2 may be a semiconductor crystal selectively grown on a surface of a semiconductor base plate. FIG. 5 shows an example of the electron emission material that employs such a substrate 2. In the electron emission material 1 shown in FIG. 5, an insulating film 12 is disposed on a surface of the semiconductor base plate 11 (the plane index of the surface is (111)), and a semiconductor crystal, which serves as the substrate 2, is grown through window potions formed in the insulating film 12. As illustrated in FIG. 6, atomic steps 3 are formed on the surface of the substrate 2, and an adsorbed layer 5 is arranged in each flat region 4 between the atomic steps 3. Such a configuration can increase the magnitude of the electric dipole formed. In addition, since semiconductor crystals can be formed by, for example, a growth technique, controlling of the density and/or direction of the atomic step 3 on the crystal surface is possible, making it easy to control the structure of the adsorbed layer 5. FIG. 6 is a schematic view in which a region near a vertex at a bottom face of the substrate 2 shown in FIG. 5 is illustrated enlarged.

In the electron emission material 1 of the present invention, the adsorbed layer 5 may further contain a metal element X (hereafter may be referred to as “element X”) excluding the element contained in the substrate 2 and the element A. Since an electric dipole can be formed further between the element X and the element A, the electron emission material is enabled to have a further reduced work function.

Although the element X is not particularly limited, an element having a large difference in electronegativity from the element A is preferable; for example, it is recommended that the adsorbed layer 5 contain as the element X at least one element selected from Au and Ag. Au and Ag have not only a large difference in electronegativity from the element A but also show a tendency to align periodically in the surface of the substrate 2 (that is, in the adsorbed layer 5).

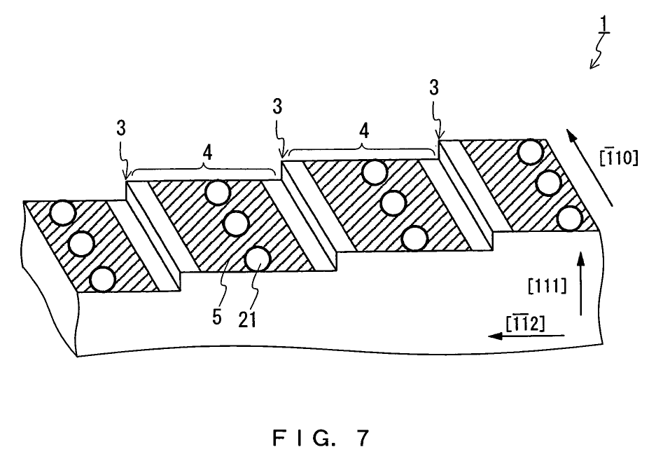

The status of the element X in the adsorbed layer 5 is not particularly limited; and for example, as illustrated in FIG. 7, adsorbed regions 21 of the element X may be formed in the adsorbed layer 5. It should be noted that although the regions 21 are shown as circles in FIG. 7 for convenience in illustration, it does not mean that three atoms of the element X are arranged in each one of the flat regions 4. In reality, assuming that a flat region 4 has 36 adsorption sites, it is sufficient that, for example, the element X is arranged onto 12 of the adsorption sites while the element A is arranged onto 6 of the adsorption sites. Although described later in Examples, this state is a state in which ⅓ atomic layer of the element X and ⅙ atomic layer of the element A are arranged in the flat region 4. Also in the case in which two or more kinds of elements are adsorbed too, the denominator of the numerical value indicating an atomic layer is a value that reflects the number of the adsorption sites that the flat region 4 has.

It is preferable that the element X be periodically aligned in the adsorbed layer 5. Due to the periodic alignment of the element X, a periodic alignment of dipole moments induced by the electric dipole is possible, making it possible to obtain a further greater dipole moment.

Although the alignment of the element X in the adsorbed layer 5 is not particularly limited, it is preferable that the alignment of the element X can be represented by a M′×N′ structure (M′ and N′ are natural numbers satisfying the expression M′>2N′). Here, the M′×N′ structure means a structure in which the size of the unit cell of the element X in the adsorbed layer 5 is M′ and N′ times of a primitive unit cell (1×1 structure) of the substrate 2 in the flat region 4 when viewed in plan from the direction perpendicular to the flat region 4. It is believed that such a structure can further suppress the occurrence of fluctuation in the shape of the atomic step 3 at an atomic level, and can further suppress fluctuation in the alignment of dipole moments induced along the atomic step 3.

In the adsorbed layer 5, the element X and the element A may be arranged in that order from the flat region 4 side. When this is the case, it is sufficient that the element X and the element A are arranged in that order in at least a portion of the region of the adsorbed layer 5 (in other words, it is sufficient that at least portions of the element X and the element A are in the above-described condition). Such a structure can further increase the magnitude of the electric dipole formed. Such an electron emission material 1 can be obtained by arranging the element X in the flat region of a semiconductor substrate having an atomic step on its surface and thereafter further arranging the element A.

An electron emission element according to the present invention will be described.

An electron emission element according to the present invention includes an electron emission layer containing the above-described electron emission material according to the present invention, and an electrode arranged so as to oppose the electron emission layer and adapted to generate a potential difference between it and the electron emission layer. Since the electron emission element of the present invention is provided with an electron emission layer containing an electron emission material in which the work function is reduced, it can obtain a high current density under a condition where the heating temperature is low; and it is possible to attain an electron emission element having good electron emission performance.

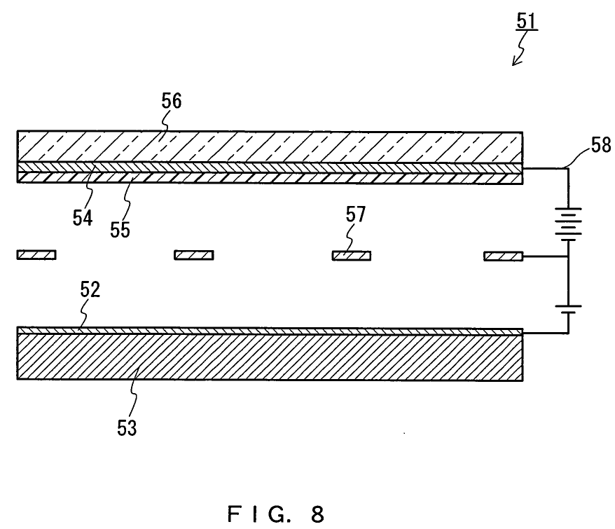

FIG. 8 shows one example of the electron emission element according to the present invention. The electron emission element 51 shown in FIG. 8 is a display device, in which an electron emission layer 52 containing the electron emission material according to the present invention is formed on a base plate 53. In addition, an accelerating electrode 54 and a phosphor layer 55 formed on a glass substrate 56 are arranged so as to oppose the electron emission layer 52. An extraction electrode 57 in a striped form is arranged between the electron emission layer 52 and the accelerating electrode 54 in a direction perpendicular to the plane of the drawing, and the electron emission layer 52, the accelerating electrode 54, and the extraction electrode 57 are electrically connected by a circuit 58. With the circuit 58, a potential difference is applied between the extraction electrode 57 and the electron emission layer 52 to bring the extraction electrode 57 side to be positive, whereby electrons are emitted from the electron emission layer 52. The emitted electrons are accelerated by the voltage applied between the accelerating electrode 54 and the electron emission layer 52, and thereafter collide with the phosphor layer 55. The phosphor layer 55 is excited by the collision, emitting light. Thus, the electron emission element 51 functions as a display. In this case, while the temperature of the electron emission layer 52 is low, a high current density can be obtained; therefore, the electron emission element 51 is enabled to reduce power consumption.

### EXAMPLES

Hereinbelow, the present invention is described in further detail with reference to Examples. It should be noted that the present invention is not limited to Examples shown below.

In Example 1, an electron emission material as shown in FIG. 1 was fabricated. The fabricating method is shown in the following.

First, a Si base plate (doped with boron to have a specific resistance of 1 kΩcm or lower), the surface of which was about 4° inclined in the [−1, −1, 2] direction from the (111) surface, was heated by passing electricity so that the temperature was elevated to 1200° C. several times in a chamber in which the degree of vacuum was brought to 1.33×10⁻⁸ Pa (1×10⁻¹⁰ Torr), to clean the surface.

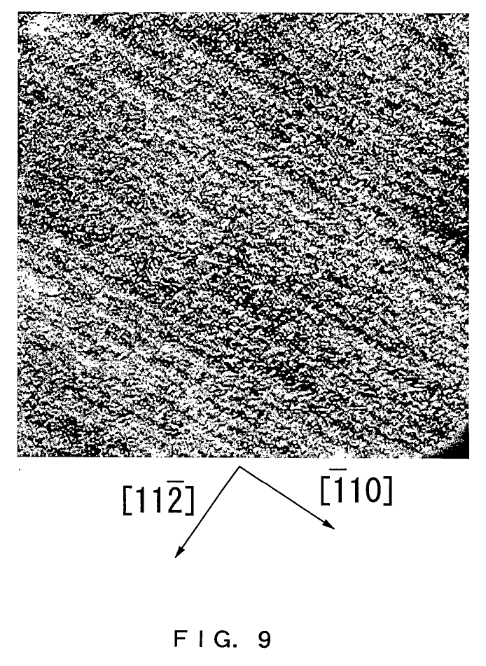

Next, the surface of the base plate after the cleaning was observed with a scanning tunneling microscope (STM). As shown in FIG. 9, a myriad of 0.31 nm-high atomic steps advancing in the [−1, 1, 0] direction were observed. The width of the flat region represented by a plane index (111) was about 4.4 nm, and the density of the atomic steps (step density) was 2.3×10⁸/m (the method of measuring the step density was the same throughout the following Examples). The observed area shown in FIG. 9 was 160 nm×160 nm.

Next, with setting the base plate temperature to 540° C., Cs was deposited on the surface of the base plate using a Cs evaporation source (made by SAES Getters Inc.) to form an adsorbed structure; thus, an electron emission material was fabricated. The deposition of Cs was carried out in a chamber in which the degree of vacuum was brought to 10.6×10⁻⁷ Pa (8×10⁻¹⁰ Torr), and the distance between the evaporation source and the surface of the base plate was set to be 3 cm. The amount of Cs deposited was determined by observing the diffraction pattern that reflects the structure of the base plate surface with the use of an electron diffraction equipment, while performing the deposition. In Example 1, ⅔ atomic layer of Cs was adsorbed onto the flat region of the base plate. It should be noted that the phrase “to adsorb ⅔ atomic layer” means that the number of the adsorption sites to which atoms are adsorbed is 2n, in the case where the number of adsorption sites existing in the surface of a base plate is 3n when viewed in plan.

Next, the surface of the electron emission material fabricated was observed and evaluated using STM and X-ray photoelectron spectroscopy. Consequently it was found that two rows of 6×1 structure of Cs (in which the brachyaxis direction in the primitive lattice of Cs matches the longitudinal direction of the atomic steps) are formed in the flat region along the atomic step.

The work function of the electron emission material thus fabricated was measured using a Kelvin probe technique and consequently found to be about 1.1 eV (the method of measuring the work function is identical throughout the following Examples). In view of the fact that the work function of the Si base plate was about 4.7 eV before Cs was deposited and the work function of the Si base plate having almost no atomic step on the surface thereof (Cs is deposited on the surface) is about 1.7 eV, it is understood that the presence of the atomic step and the adsorbed structure of Cs reduced the work function. Surf. Sci., vol. 99, p. 157 (1980) shows that, with a Si substrate whose surface is clean and inclined (the plane index of the surface being (111)), the work function reduces about 0.1 eV for each increase of 1.7° in the inclination angle (in other words, according to an increase in the density of the atomic steps). The work function reduced about 0.6 eV in the electron emission material of the present invention; it is believed that this further reduction in the work function was achieved by the synergistic effect of the atomic steps and the adsorbed structure of Cs.

Next, the fabricated electron emission material was placed onto a conductive heating plate, and its temperature-current profile was measured with a spherical gold electrode (diameter: 150 μm) opposed above the electron emission material (the method of measuring temperature-current profile is identical throughout the following Examples). The distance between the electron emission material and the gold electrode was set to be 2 mm. The obtained profile agreed with the Richardson-Dushmann equation, and the value of the work function obtained from the above-noted profile was also about 1.1 eV. The temperature-current profile was compared with that of a mixture of barium oxide, strontium oxide, and calcium oxide, which is a conventional electron emission material, and consequently, it was demonstrated that the fabricated electron emission material was capable of attaining the same current density at a temperature about 230° C. lower than that with the conventional material. The measurement was continued while maintaining the temperature at 440° C., and proved that approximately the same current density was obtained even 10000 hours later.

In Example 1, the height of the atomic step was equal to the interval between the flat surfaces, but similar advantageous effects were obtained even when the height of the atomic step was different from the interval between the flat surfaces. In particular, when the height of the atomic step was an integer multiple of the interval of the flat surfaces, it was possible to obtain an electron emission material having a further reduced work function.

### EXAMPLE 2

In Example 2, an electron emission material as shown in FIG. 1 was fabricated using as a substrate a p-type Si base plate the surface of which was inclined about 1.7° in the [1, 1, −2] direction from the (111) surface.

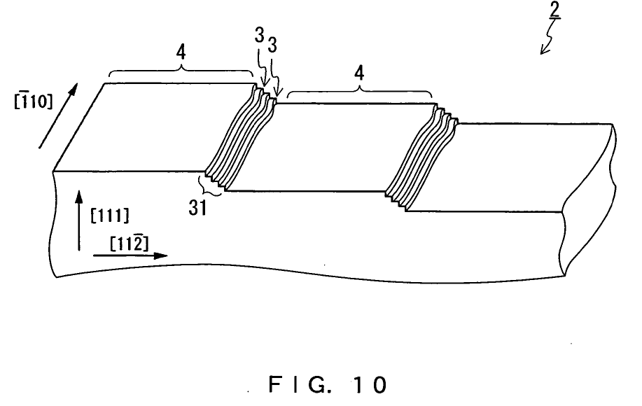

First, the surface of the base plate was cleaned in the same manner as in Example 1. The surface of the base plate that had been cleaned was observed using STM. As shown in FIG. 10, a region in which atomic steps 3 are closely packed (step bunching 31) was observed. The longitudinal direction of the step bunching 31 was approximately along the [−1, 1, 0] direction, and meander-like shapes at the atomic level were observed in each of the atomic steps 3 in the step bunching 31.

Next, Cs was deposited on the surface of the base plate in the same manner as in Example 1 while observing it with STM. As a result of the observation, it was found that Cs was selectively adsorbed onto the step bunching 31 portion in the surface of the base plate, not onto the flat regions 4, and grew in the [1, 1, −2] direction as the amount of Cs adsorbed increased, finally forming an electron emission material similar to that shown in FIG. 1. As the Cs was deposed, the fluctuation in the atomic steps 3 disappeared. It should be noted that in Example 2, ⅔ atomic layer of Cs was adsorbed as in Example 1.

Next, the surface of the fabricated electron emission material was observed using STM. It was found that the atomic steps with a height of 0.31 nm were formed at approximately equal intervals, and the density of the atom steps was 2.3×10⁸/m. In a flat region between the atomic steps, one row of a 6×1 structure of Cs was formed along the atomic steps.

Next, the temperature of the base plate was lowered to room temperature, and thereafter the base plate was exposed into an oxygen atmosphere with a partial pressure of 1.33×10⁻⁶ Pa (1×10⁻⁸ Torr) for 5 minutes. The surface of the base plate after the exposure was evaluated by X-ray photoelectron spectroscopy. Consequently, it was found that the peak position derived from the 3d^{5/2} orbit of Cs shifted toward a low energy side, which indicates that Cs and O (oxygen) were chemically bonded.

The work function of the electron emission material thus fabricated was measured and found to be about 1.1 eV. It is believed that the work function was considerably reduced because of the synergistic effect of the atomic steps and the adsorbed structure of Cs—O.

Next, the temperature-current profile thereof was measured. The obtained profile proved to be in agreement with the Richardson-Dushmann equation, and the value of the work function obtained from the profile was also about 1.1 eV. The temperature-current profile was compared with that of a mixture of barium oxide, strontium oxide, and calcium oxide, and consequently, it was demonstrated that the fabricated electron emission material was capable of attaining the same current density at a temperature about 230° C. lower than that with the conventional material. Furthermore, the measurement was continued while maintaining the temperature at 440° C., and approximately the same current density was obtained even 10000 hours later.

### EXAMPLE 3

In Example 3, an electron emission material was fabricated in the same manner as in Example 1 except that K was employed in place of Cs as the atoms to be adsorbed on the flat region. However, the temperature of the base plate during the deposition was set at 400° C., the degree of vacuum was 12.0×10⁻⁷ Pa (9×10⁻¹⁰ Torr), and a K evaporation source made by SAES Getters Inc. was used for the deposition. In addition, ⅓ atomic layer of K was adsorbed on the flat region of the base plate.

The surface of the fabricated electron emission material was evaluated using electron diffraction analysis. It was consequently found that a 3×1 structure of K was formed in the flat region of the base plate. Moreover, the surface was observed using STM, and it was found that the step density was 2.3×10⁸/m and 4 rows of 3×1 structure of K were formed along the atomic steps in the flat region.

The work function of the electron emission material thus fabricated was measured and found to be about 1.3 eV. It is believed that the work function was considerably reduced because of the synergistic effect of the atomic steps and the adsorbed structure of K.

Next, the temperature-current profile was measured. The obtained profile proved to be in agreement with the Richardson-Dushmann equation, and the value of the work function obtained from the profile was also about 1.3 eV. The temperature-current profile was compared with that of the mixture of barium oxide, strontium oxide, and calcium oxide, and consequently, it was demonstrated that the fabricated electron emission material was capable of attaining the same current density at a temperature about 120° C. lower than that with the conventional material. Furthermore, the measurement was continued while maintaining the temperature at 550° C., and approximately the same current density was obtained even 10000 hours later.

### EXAMPLE 4

In Example 4, an electron emission material was fabricated in the same manner as in Example 2 except that K was employed in place of Cs as the atoms to be adsorbed on the flat region. Additionally, the conditions during the deposition were the same as those in Example 3, and ⅓ atomic layer of K was adsorbed on the flat region of the base plate.

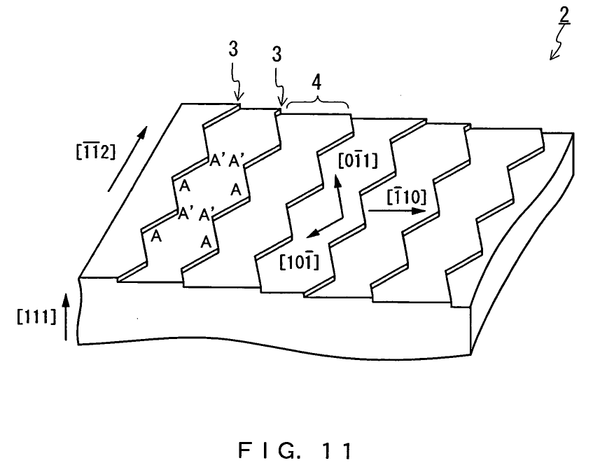

The surface of the base plate was observed using STM before K was adsorbed; consequently, it was found that, as shown in FIG. 11, atomic steps 3 in a zigzag pattern and flat regions 4 in which the width was varied periodically according to the shape of the atomic steps 3 were observed. The atomic steps 3 included two kinds of steps, one advancing approximately in the [0,−1,1] direction and the other advancing in the [1,0,−1] direction. The advancing direction (the longitudinal direction) of the atomic steps 3 as a whole was the [−1, −1, 2] direction, which is perpendicular to the inclination direction ([31 1, 1, 0]) of the base plate. It is believed that such a shape resulted because atomic steps tend to form in the [−, 1, 0], [0, −1 ,1], and [1, 0, −1] directions on a Si (111) surface. It should be noted that the just-noted three directions are equivalent to one another because the silicon (111) surface has threefold symmetry. As illustrated in FIG. 11, a portion having a maximum width (A-A) and a portion having a minimum width (A′-A′) existed periodically in the flat region 4. Although it is not clear why the flat region 4 has such a shape, the reason may be that the atomic steps 3 are not randomly formed but an interaction acts between the atomic steps 3 adjacent to each other during the formation of the atomic steps 3.

After K was adsorbed, the surface of the fabricated electron emission material was observed using STM. Consequently, it was found that the adsorbed structure of K was formed on the flat region 4, and an electron emission material as shown in FIG. 3 was obtained. The shape and position of the atomic steps 3 did not change before and after the adsorption of K. The step density in the surface of the base plate was 1×10⁸/m, and a plurality of 3×1 structures of K were formed in the flat region along the atomic steps.

The work function of the electron emission material thus fabricated was measured and found to be about 1.2 eV. It is believed that the work function was considerably reduced because of the synergistic effect of the atomic steps and the adsorbed structure of K. It is believed that the work function was reduced further than Example 3 because angular portions (A and A′ shown in FIG. 3) existed in the atomic steps 3, although the step density of the obtained electron emission material was smaller than that of the electron emission material fabricated in Example 3.

Next, the temperature-current profile was measured. The obtained profile proved to be in agreement with the Richardson-Dushmann equation, and the value of the work function obtained from the profile was also about 1.2 eV. The temperature-current profile was compared with that of the mixture of barium oxide, strontium oxide, and calcium oxide, and consequently, it was demonstrated that the fabricated electron emission material was capable of attaining the same current density at a temperature about 120° C. lower than that with the conventional material. Furthermore, the measurement was continued while maintaining the temperature at 550° C., and approximately the same current density was obtained even 10000 hours later.

### EXAMPLE 5

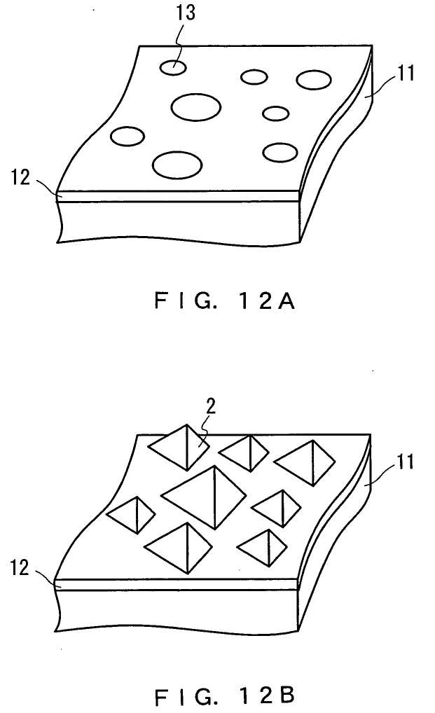

In Example 5, an electron emission material was fabricated using, as a substrate, a semiconductor crystal selectively grown on a semiconductor base plate. Referring to FIGS. 12A and 12B, the fabricating method is described.

First, an oxide film 12 (film thickness: 0.3 nm) was formed on a surface (plane index (111)) of a Si base plate 11, which had been cleaned in the same manner as in Example 1, with the oxidation conditions of a substrate temperature of 630° C., an oxygen partial pressure of 2.66×10⁻⁴ Pa (2×10⁻⁶ Torr), and a holding time of 10 minutes.

Next, the temperature of the base plate 11 was gradually elevated to about 720° C., whereby the oxide film 12 was partially thermodesorbed to form windows 13 (FIG. 12A). The temperature elevation was performed while observing the surface of the base plate 11 (the oxide film 12) using STM, and the temperature of the base plate 11 was dropped at the point when the windows 13 became a predetermined size to stop the thermodesorption. Usually, the size of the windows 13 do not become uniform with this method since the thermodesorption of the oxide film 12 starts randomly; nevertheless, a plurality of windows 13 in the order of nanometers can be formed on the surface of the base plate 11.

Next, as illustrated in FIG. 12B, by introducing disilane (Si₂H₆) into a chamber at a partial pressure of 4×10⁻² Pa (3×10⁴ Torr), a substrate 2 composed of a Si crystal was selectively grown on the windows 13. The surface of the oxide film 12 have few dangling bonds and neither decomposition of disilane nor growth of Si occurs easily; for this reason, the Si crystal selectively grew only on the windows 13. An observation was performed with STM while growing the Si crystal, and consequently, it was confirmed that two-dimensional growth took place in each one layer. The shape of the Si crystal resulted in approximately triangular pyramids or frustums of triangular pyramids, reflecting the symmetry of the base plate 11, and the gradient of the side faces increased as the growth proceeded. The introduction of disilane into the chamber was stopped at the point when the gradient became about 8°, to stop the growth of the Si crystal.

Next, Cs was deposited on the surface of the Si crystal, serving as the substrate 2, in the same manner as in Example 1, and an electron emission material was thus fabricated. The surface of the fabricated electron emission material was observed using STM and confirmed to have the structures shown in FIGS. 5 and 6. In addition, the shape of the Si crystal was almost maintained before and after the deposition of Cs. The step density of the Si crystal surface was 4.5×10⁸/m, and almost no Cs was deposited on the surface of the oxide film 12.

The work function of the electron emission material thus fabricated was measured and found to be about 1.1 eV. It is believed that the work function was considerably reduced because of the synergistic effect of the atomic steps and the adsorbed structure of Cs.

Next, the temperature-current profile was measured. The obtained profile proved to be in agreement with the Richardson-Dushmann equation, and the value of the work function obtained from the profile was also about 1.1 eV. The temperature-current profile was compared with that of the mixture of barium oxide, strontium oxide, and calcium oxide, and consequently, it was demonstrated that the fabricated electron emission material was capable of attaining the same current density at a temperature about 230° C. lower than that with the conventional material. Furthermore, the measurement was continued while maintaining the temperature at 440° C., and approximately the same current density was obtained even 10000 hours later.

### EXAMPLE 6

In Example 6, an electron emission material as shown in FIG. 7 was fabricated. The fabricating method is shown in the following.

First, a Si base plate (doped with boron to have a specific resistance of 1 kΩcm or lower), the surface of which was about 9.5° inclined in the [−, −1, 2] direction from the (111) surface, was heated by passing electricity so that the temperature was elevated to 1200° C. several times in a chamber in which the degree of vacuum was brought to 1.33×10⁻¹⁰ Pa (1×10⁻¹⁰ Torr), to clean the surface.

Next, the surface of the base plate after the cleaning was observed with a scanning tunneling microscope (STM). A myriad of 0.31 nm-high atomic steps advancing in the [−, 1, 0] direction were observed. The width of the flat region represented by a plane index (111) was about 1.9 nm, and the density of the atomic steps (step density) was 5.3×10⁸/m.

Subsequently, with setting the substrate temperature to 600° C., Au was deposited on the surface of the base plate, using a Au evaporation source in which gold was adhered to a tungsten filament. The deposition of Au was performed in a chamber in which the degree of vacuum was set at 4×10⁻⁷ Pa (3×10⁻¹⁰ Torr), and the distance between the surface of the base plate and the evaporation source was 15 cm.

Next, with setting the substrate temperature to 300° C., Cs was deposited on the surface of the base plate using a Cs evaporation source (made by SAES getters Inc.) to form an adsorbed structure; thus, an electron emission material was fabricated. The deposition of Cs was performed in a chamber in which the degree of vacuum was set at 10.6×10⁻⁷ Pa (8×10⁻¹⁰ Torr), and the distance between the surface of the base plate and the evaporation source was 3 cm. The amounts of Au and Cs deposited were determined by observing the diffraction pattern that reflects the structure of the base plate surface using an electron diffraction equipment, while performing the deposition. In Example 6, ⅓ atomic layer of Au and ⅙ atomic layer of Cs were adsorbed onto the flat region of the base plate.

Next, the surface of the fabricated electron emission material was observed and evaluated using STM and X-ray photoelectron spectroscopy. Consequently it was found that a 5×1 structure of Au (wherein the brachyaxis direction in the primitive lattice of Au matches the longitudinal direction of the atomic step) was formed on the flat region along the atomic steps, and the width of the flat region was approximately the same as the size of the unit cell of the 5×1 structure of Au. In addition, a 5×1 structure of Cs was formed on the flat region, and part of Cs atoms sat atop the Au atoms (in other words, Au atoms and Cs atoms are arranged in that order from the flat region side). The Cs atoms that did not sit on the Au atoms were adsorbed on the surface of the base plate.

The work function of the electron emission material thus fabricated was measured and found to be about 1.1 eV. It is believed that the work function was considerably reduced because of the synergistic effect of the atomic steps, the adsorbed structure of Cs, and the adsorbed structure of Au.

Next, the temperature-current profile was measured. The obtained profile proved to be in agreement with the Richardson-Dushmann equation, and the value of the work function obtained from the profile was also about 1.1 eV. The temperature-current profile was compared with that of the mixture of barium oxide, strontium oxide, and calcium oxide, and consequently, it was demonstrated that the fabricated electron emission material was capable of attaining the same current density at a temperature about 220° C. lower than that with the conventional material. Furthermore, the measurement was continued while maintaining the temperature at 430° C., and approximately the same current density was obtained even 10000 hours later.

### EXAMPLE 7

In Example 7, an electron emission material as shown in FIG. 7 was fabricated using, as a substrate, a p-type Si base plate having a surface that was inclined about 8.5° in the [1, 1, −2] direction from the (111) surface.

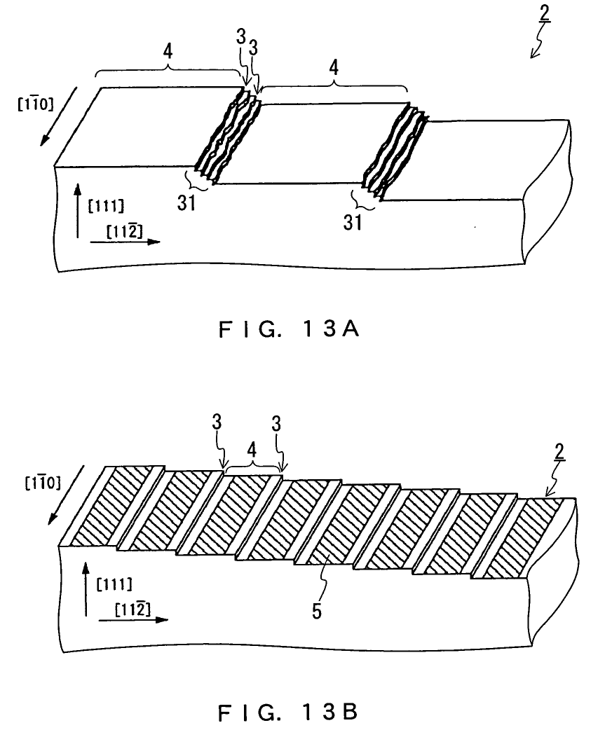

First, the surface of the base plate was cleaned in the same manner as in Example 6. The surface of the base plate that had been cleaned was observed using STM. As shown in FIG. 13A, a region in which atomic steps 3 are closely packed (step bunching 31) was observed. The longitudinal direction of the step bunching 31 was approximately along the [−, 1, 0] direction, and meander-like shapes at the atomic level were observed in each of the atomic steps 3 in the step bunching 31.

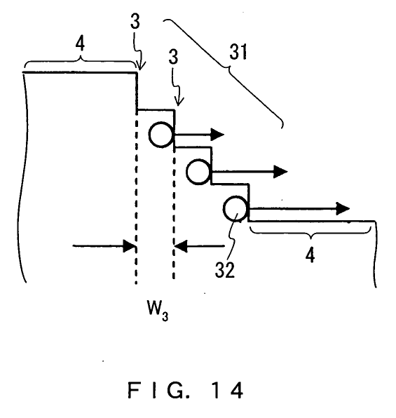

Next, ⅓ atomic layer of Au was deposited on the surface of the base plate in the same manner as in Example 6 while observing it with STM. As a result of the observation, it was found that Au was selectively adsorbed onto the step bunching 31 portion in the surface of the base plate, not onto the flat regions 4. As Au was adsorbed onto the step bunching 31, the Si atoms 32 constituting the step bunching 31 moved in the direction along the flat regions 4, as illustrated in FIG. 14. It is believed that the Si atoms 32 moved so as to be in a more stable state because the width W₃ of each atomic step 3 in the step bunching 31 is less than the unit cell of the adsorbed structure formed in depositing ⅓ atomic layer of Au. As the Si atoms 32 moved, the distances between the atomic steps 3 in the step bunching 31 widened (the width of the flat regions 4 represented by plane index(111) widened), and finally, atomic steps 3 were formed at approximately equal intervals as shown in FIG. 13B, resulting in a structure in which an adsorbed structure of Au (an adsorbed layer 5 composed of Au) was formed in each flat region 4 located between the atomic steps 3. The meander-like shapes of the atomic steps 3 disappeared, and the advancing direction (the longitudinal direction) thereof was precisely the [1, −1, 0] direction. The density of the atomic steps 3 was 4.8×10⁸/m, and the width of the flat regions 4 was uniformly 2.1 nm.

Next, ⅙ atomic layer of Cs was adsorbed onto the flat regions in the same manner as in Example 6. The surface of the fabricated electron emission material was observed using STM, and consequently it was found that a 5×1 structure of Au and a 5×1 structure of Cs were formed along the atomic steps.

The work function of the electron emission material thus fabricated was measured and found to be about 1.1 eV. It is believed that the work function was considerably reduced because of the synergistic effect of the atomic steps, the adsorbed structure of Cs, and the adsorbed structure of Au.

Next, the temperature-current profile was measured. The obtained profile proved to be in agreement with the Richardson-Dushmann equation, and the value of the work function obtained from the profile was also about 1.1 eV. The temperature-current profile was compared with that of the mixture of barium oxide, strontium oxide, and calcium oxide, and consequently, it was demonstrated that the fabricated electron emission material was capable of attaining the same current density at a temperature about 220° C. lower than that with the conventional material. Furthermore, the measurement was continued while maintaining the temperature at 430° C., and approximately the same current density was obtained even 10000 hours later.

### EXAMPLE 8

In Example 8, after adsorbed structures of Au and Cs were formed in the same manner as in Example 7, an electron emission material fabricated was exposed to an oxidizing atmosphere using the same method as in Example 2 to chemically bond Cs and O. The bonding of Cs and O was confirmed in the same manner as in Example 2.

The work function of the electron emission material thus fabricated was measured and found to be about 1.05 eV. It is believed that the work function was considerably reduced because of the synergistic effect of the atomic steps, the adsorbed structure of Cs—O, and the adsorbed structure of Au.

Next, the temperature-current profile was measured in the same manner as in Example 1. The obtained profile proved to be in agreement with the Richardson-Dushmann equation, and the value of the work function obtained from the profile was also about 1.05 eV. Furthermore, the measurement was continued, and the change over time of the thermionic current was very small.

### EXAMPLE 9

In Example 9, an electron emission material was fabricated in the same manner as in Example 6 except that K was employed in place of Cs as the atoms to be adsorbed on the flat region after the formation of the adsorbed structure of Au. Additionally, the temperature of the base plate in depositing K was set to be 300° C., the degree of vacuum was 12.0×10⁻⁷ Pa (9×10⁻¹⁰ Torr), and a K evaporation source made by SAES Getters Inc. was used for the deposition. Also, ⅙ atomic layer of K was adsorbed.

The work function of the electron emission material thus fabricated was measured and found to be about 1.3 eV. It is believed that the work function was considerably reduced because of the synergistic effect of the atomic steps, the adsorbed structure of K, and the adsorbed structure of Au.

Next, the temperature-current profile was measured. The obtained profile proved to be in agreement with the Richardson-Dushmann equation, and the value of the work function obtained from the profile was also about 1.3 eV. The temperature-current profile was compared with that of the mixture of barium oxide, strontium oxide, and calcium oxide, and consequently, it was demonstrated that the fabricated electron emission material was capable of attaining the same current density at a temperature about 120° C. lower than that with the conventional material. Furthermore, the measurement was continued while maintaining the temperature at 540° C., and approximately the same current density was obtained even 10000 hours later.

### EXAMPLE 10

In Example 10, a semiconductor crystal was selectively grown on a semiconductor base plate in a similar manner to Example 5, and an electron emission material was fabricated using the formed semiconductor crystal as a substrate.

First, an oxide film 12 (film thickness: 0.3 nm) was formed on a surface (plane index (111)) of a Si base plate 11, which had been cleaned in the same manner as in Example 6, under the oxidation conditions of a substrate temperature of 620° C., an oxygen partial pressure of 2.66×10⁻⁴ Pa (2×10⁻⁶ Torr), and a holding time of 10 minutes.

Next, the temperature of the base plate 11 was gradually elevated to about 720° C., whereby the oxide film 12 was partially thermodesorbed to form windows 13.

Next, by introducing disilane (Si₂H₆) into a chamber at a partial pressure of 4×10⁻² Pa (3×10⁻⁴ Torr), a substrate 2 composed of a Si crystal was selectively grown on the windows 13. An observation was performed with STM while growing the Si crystal, and consequently, it was confirmed that two-dimensional growth took place in each one layer. The shape of the Si crystal resulted in approximately triangular pyramids or frustums of triangular pyramids, reflecting the symmetry of the base plate 11, and the gradient of the side faces increased as the growth proceeded. The introduction of disilane into the chamber was stopped at the point when the gradient became about 15°, to stop the growth of the Si crystal.

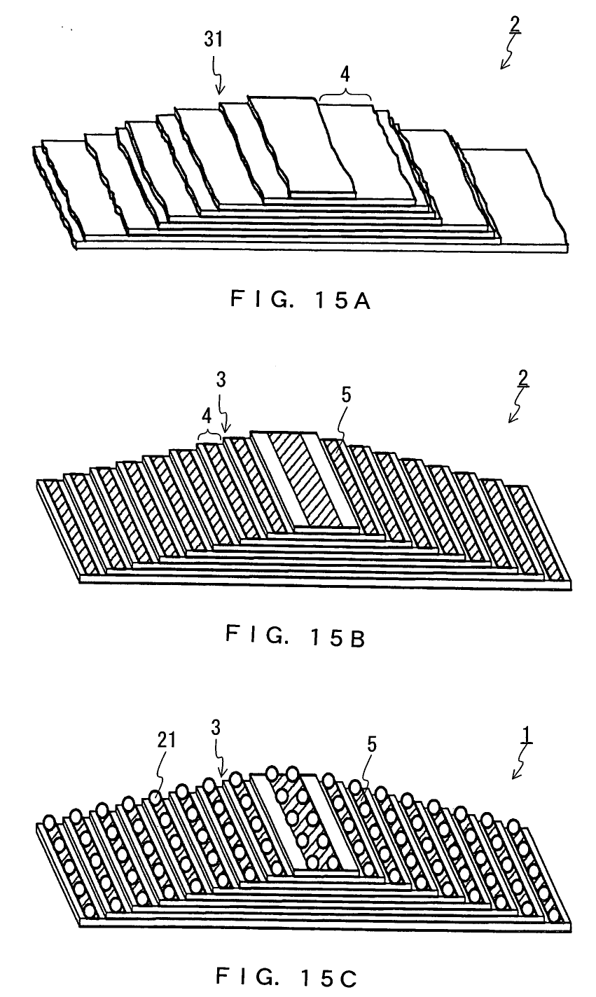

Subsequently, the surface of the formed Si crystal was observed using STM. As shown in FIG. 15A, a region in which atomic steps 3 are closely packed (step bunching 31) was observed. The longitudinal direction of the step bunching 31 was approximately along the [1, −1, 0] direction, and meander-like shapes at the atomic level were observed in each of the atomic steps 3 in the step bunching 31.

Subsequently, with setting the substrate temperature to 600° C., ⅓ atomic layer of Ag was deposited on the surface of the base plate, using a Ag evaporation source in which silver was adhered to a tungsten filament. The deposition of Ag was performed in a chamber in which the degree of vacuum was set at 4×10⁻⁷ Pa (3×10⁻¹⁰ Torr), and the distance between the surface of the base plate and the evaporation source was 15 cm.

After Ag was deposited the surface of the Si crystal was observed using STM. As shown in FIG. 15B, atomic steps 3 were formed at approximately equal intervals, and an adsorbed structure of Ag (an adsorbed layer 5 composed of Ag) was formed on each flat region 4 having a uniform width. The meander-like shapes of the atomic steps 3 disappeared, and the advancing direction thereof was precisely the [1, −1, 0] direction. The density of the atomic steps 3 was 1×10⁹/m.

Next, using a Ba evaporation source (made by SAES Getters Inc.) in place of the Cs evaporation source, ⅙ atomic layer of Ba was adsorbed in a similar manner to that in Example 6, and an electron emission material was thus fabricated. The surface of the fabricated electron emission material was observed using STM. It was found that as shown in FIG. 15C, an adsorbed layer 5 including an adsorbed structure 21 of Ba was formed in each flat region, and a 3×1 structure of Ag and a 3×1 structure of Ba along the atomic steps 3 were formed.

The work function of the electron emission material thus fabricated was measured and found to be about 1.1 eV. It is believed that the work function was considerably reduced because of the synergistic effect of the atomic steps, the adsorbed structure of Ba—O, and the adsorbed structure of Ag.

Next, the temperature-current profile was measured. The obtained profile proved to be in agreement with the Richardson-Dushmann equation, and the value of the work function obtained from the profile was also about 1.1 eV. Furthermore, the measurement was continued, and the change over time of the thermionic current was very small.

In Example 10, the windows were formed window utilizing the thermodesorption of the oxide film; however, it is possible to form the windows by fixing the probe of STM about 100 nm apart from the surface of the oxide film and then irradiating the oxide film with an electron beam (incident energy: 20 eV or greater) for a predetermined duration by field electron emission. With this method, the windows can be formed in a uniform size, for example, at a diameter of about 20 nm. The method using the thermodesorption and the method using electron emission may be carried out without restricting the plane index or inclination angle of the surface of the base plate. In addition, even with the use of electron beam exposure or a photolithography technique, it was possible to form the windows relatively easily, although it was difficult to form windows into a nanometer order size. Similar advantageous effects were attained when any of the foregoing methods was used to form the windows.

The method of forming a substrate having atomic steps on a surface thereof did not affect the obtained work function value. For example, similar advantageous effects were attained when a substrate was formed by any of the following; an etching method through a physical or chemical technique, a growth method, a deposition method, and combinations thereof. In addition, similar advantageous effects were attained also when a substrate having atomic steps was formed by segregating P (phosphorus) and B (boron), which are trace elements that constitute a semiconductor, in the vicinity of the substrate surface to form comb-shaped atomic steps.

Although Examples 1 through 10 employed a Si (111) surface as the flat region, similar advantageous effects were attained also when the plane index (hkl) of the flat region satisfy the expressions 0≦h, k, l≦3, wherein at least two values selected from h, k and l are positive. In this case, the more abrupt the atomic step was and the higher the atomic step was, the less the obtained work function value.

In the case of using a Si semiconductor as the substrate, the conduction type of Si did not affect the work function value obtained. Furthermore, similar advantageous effects were attained also in the case of using a base plate composed of an elemental semiconductor such as Ge or C, or a base plate composed of a compound semiconductor such as SiGe, GaAs, InGaAs, InP, GaN, or AlN.

Although Examples 1 through 10 employed Cs, K, and Ba as the element A, it was possible to attain similar advantageous effects also using at least one element A selected from Li, Na, Ca, Rb, Sr, and Sc.

By varying the longitudinal direction of the atomic steps and the fundamental vector of the unit cell in the adsorbed structure, it was possible to control the size and direction of the domain of the adsorbed structure and the type of the adsorbed structure. For example, by substantially matching the longitudinal direction of the atomic steps and the fundamental vector of the unit cell in the adsorbed structure, it was possible to selectively form a specific adsorbed structure. In addition, by selecting the inclination direction and/or inclination angle of the base plate, it was possible to control the proportion of the equivalent adsorbed structure, the longitudinal direction of the atomic steps, and/or the density of the atomic steps.

When the temperature of the substrate was varied in adsorbing the element A onto a surface thereof, the effect of reducing the work function was found to be great in a temperature region of about 700° C. or lower (preferably, 500° C. or lower).

### EXAMPLE 11

In Example 11, an electron emission element was fabricated using the electron emission materials prepared in the manner described in Examples 1 and 2, and the characteristics thereof were evaluated.

First, the electron emission materials 1 fabricated in Examples 1 and 2 were used, as they were, as a base plate 53 and an electron emission layer 52 (in the electron emission material 1, the substrate 2 corresponds to the base plate 53 and the adsorbed layer 5 corresponds to the electron emission layer 52), and a mesh-like extraction electrode 57 (with 100 meshes) made of stainless steel was arranged at a distance of 2 mm away from the electron emission layer 52, which were electrically connected to each other by a circuit 58.

Next, the entire element was accommodated in a vacuum bath, the temperature of the electron emission layer 52 was set to 430° C., and a voltage of 100 V was applied between the extraction electrode 57 and the electron emission layer 52. The current density obtained was 1A/cm².

Subsequently, an accelerating electrode 54 made of ITO and formed on a glass substrate 56 and a phosphor layer 55 containing a ZnS-based phosphor were arranged so as to oppose the electron emission layer 52, and the accelerating electrode 54 and the electron emission layer 52 were electrically connected by the circuit 58. The electron emission element 51 thus fabricated was accommodated in a vacuum bath, and a voltage of 100 V and an acceleration voltage of 3 k V were applied between the extraction electrode 57 and the electron emission layer 52, and between the accelerating electrode 54 and the electron emission layer 52, respectively. Consequently, light emission from the phosphor layer 55 was confirmed. Here, the light emission characteristics of the phosphor layer 55 were evaluated and it was found a light intensity of 200 cd/m² to 300 cd/m² was obtained. To control the light intensity, the amount of current applied to the phosphor layer 55 can be changed by varying the voltage applied between the extraction electrode 57 and the electron emission layer 52, or the electron energy applied to the phosphor layer 55 can be changed by varying the voltage applied between the accelerating electrode 54 and the electron emission layer 52.

Moreover, similar results were obtained also when the base plate 53 and the electron emission layer 52 were formed by coating an electron emission material (fabricated according to Example 1 or 2) that was pulverized into a granular form, then mixed with an inorganic and/or organic binder(s), and then coated onto the base plate.

### EXAMPLE 12

In Example 12, an electron emission element was fabricated in the same manner as in Example 11 and the characteristics thereof were evaluated. The electron emission material used was the electron emission material fabricated in Example 7.

The fabricated electron emission element 51 was accommodated in a vacuum bath, and thereafter, with setting the temperature of the electron emission layer 52 to 440° C., a voltage of 100 V was applied between the extraction electrode 57 and the electron emission layer 52; as a result, the current density obtained was 1A/cm².

Next, a voltage of 100 V was applied between the extraction electrode 57 and the electron emission layer 52 and an acceleration voltage of 3 kV between the accelerating electrode 54 and the electron emission layer 52. Consequently, light emission from the phosphor layer 55 was confirmed. An evaluation of the light emission characteristics of the phosphor layer 55 proved that a light intensity of 300 cd/m² to 400 cd/m² was obtained.

As has been described above, the present invention makes it possible to provide an electron emission material in which the work function is reduced. It should be noted that although a technique using electric field emission has been studied for long years as an electron source that operates at room temperature, there are problems in the manufacturing method in the current state of art; for example, structures having a radius of curvature in the order of several ten nanometers must be manufactured uniformly. With the electron emission material of the present invention, the precision demanded for the radius of curvature is considerably alleviated because reduction in the work function is achieved, and therefore, the invention will increase the feasibility of an electron source using electric field emission.

Furthermore, the present invention makes it possible to provide an electron emission element that shows excellent electron emission performance and attains lower power consumption and/or higher current density than conventional elements. The electron emission element of the present invention is not particularly limited and may be applied to various electronic devices, such as display devices, cathode-ray tubes, emitters, light sources, and electron guns.

The present invention may be embodied in other forms without departing from the spirit or essential characteristics thereof The presently disclosed embodiments are to be considered in all respects as illustrative and not restrictive. The scope of the invention is indicated by the appended claims rather than by the foregoing description, and all changes which come within the meaning and range of equivalency of the claims are intended to be embraced therein.

1. An electron emission material comprising: a semiconductor substrate having a plurality of atomic steps on a surface thereof and a flat region between two of the atomic steps adjacent to each other; and an adsorbed layer arranged in the flat region; wherein
the adsorbed layer contains at least one element selected from an alkali metal element, an alkaline-earth metal element, and Sc.

2. The electron emission material according to claim 1, wherein the adsorbed layer contains at least one element selected from Li, Na, K, Rb, Cs, Ca, Sr, Ba, and Sc.

3. The electron emission material according to claim 1, wherein the adsorbed layer further contains oxygen.

4. The electron emission material according to claim 1, wherein the semiconductor substrate comprises a crystalline semiconductor of Si.

5. The electron emission material according to claim 1, wherein the longitudinal directions of the atomic steps adjacent to each other are substantially parallel to each other.

6. The electron emission material according to claim 1, wherein the flat region is a crystal surface represented by a plane index (hkl) where h, k, and l satisfy the expressions 0≦h<3, 0≦k≦3, and 0≦l≦3, respectively, and at least two values selected from h, k and l are positive.

7. The electron emission material according to claim 6, wherein the flat region is a crystal surface represented by a plane index (111).

8. The electron emission material according to claim 1, wherein the length of the flat region perpendicular to the longitudinal direction of the atomic steps varies periodically.

9. The electron emission material according to claim 1, wherein the length of the flat region perpendicular to the longitudinal direction of the atomic steps is 100 nm or less.

10. The electron emission material according to claim 8, wherein the length of the flat region perpendicular to the longitudinal direction of the atomic steps varies in a zigzag pattern.

11. The electron emission material according to claim 1, wherein the semiconductor substrate is a semiconductor crystal selectively grown on a semiconductor base plate.

12. The electron emission material according to claim 11, wherein the semiconductor substrate is a semiconductor crystal grown on a window portion formed in an oxide film arranged on a surface of a semiconductor base plate.

13. The electron emission material according to claim 11, wherein the surface of the base plate is a crystal surface represented by a plane index (111).

14. The electron emission material according to claim 1, wherein the adsorbed layer has a structure in which the at least one element is arranged at a portion of adsorption sites existing on a surface of the flat region.

15. The electron emission material according to claim 1, wherein the at least one element are periodically aligned in the adsorbed layer.

16. The electron emission material according to claim 15, wherein the alignment interval of the at least one element is greater along the direction perpendicular to the longitudinal direction of the atomic step than that along the longitudinal direction.

17. The electron emission material according to claim 16, wherein the alignment of the at least one element is represented by a M×N structure, where M and N are natural numbers satisfying the expression M>2N.

18. The electron emission material according to claim 17, wherein, in the alignment of the at least one element, a value corresponding to the alignment along the longitudinal direction of the atomic step is the N.

19. The electron emission material according to claim 1, wherein the adsorbed layer further contains a metal element X excluding the at least one element and an element contained in the semiconductor substrate.

20. The electron emission material according to claim 19, wherein the metal element X is at least one element selected from Au and Ag.

21. The electron emission material according to claim 19, wherein the metal element X are periodically aligned in the adsorbed layer.

22. The electron emission material according to claim 21, wherein the alignment of the metal element X is represented by a M′×N′ structure, where M′ and N′ are natural numbers satisfying the expression M′>2N′.

23. The electron emission material according to claim 19, wherein the metal element X and the at least one element are arranged in that order from the flat region.

24. An electron emission element comprising:
an electron emission layer including an electron emission material; and
an electrode arranged so as to oppose the electron emission layer and adapted to generate a potential difference between it and the electron emission layer; wherein
the electron emission material comprises a semiconductor substrate having a plurality of atomic steps on a surface thereof and a flat region between two of the atomic steps adjacent to each other; and an adsorbed layer arranged in the flat region; and
the adsorbed layer contains at least one element selected from an alkali metal element, an alkaline-earth metal element, and Sc.
